(19) United States
(12) Patent Application Publication
(10) Pub. No.: US 2026/0059923 A1
(43) Pub. Date: Feb. 26, 2026

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventors: Weilong ZHOU, Wuhan (CN); Liang SUN, Wuhan (CN); Sheng CHEN, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 19/041,937

(22) Filed: Jan. 30, 2025

Related U.S. Application Data
(63) Continuation of application No. PCT/CN2024/114995, filed on Aug. 28, 2024.

(30) Foreign Application Priority Data
Aug. 23, 2024 (CN) 202411173816.4

(51) Int. Cl. H10H 29/856; H10H 29/34

(52) U.S. Cl. CPC H10H 29/856; H10H 29/34

(57) ABSTRACT

A display panel and a display device are provided in the embodiment of the present application. The display panel includes: a driving substrate; at least two light-emitting units, stacked on the driving substrate in sequence along the light-emitting direction of the display panel; and a reflecting layer, disposed between two adjacent light-emitting units. The reflecting layer includes a first reflecting unit and a second reflecting unit disposed at an interval. The first reflecting unit is disposed between two adjacent light-emitting units. The second reflecting unit is disposed at the periphery of the first reflecting unit. The first reflecting unit and the second reflecting unit cooperate to make part of the light of the light-emitting unit emit in a direction perpendicular to the driving substrate after secondary reflection.

### CROSS-REFERENCE TO RELATED APPLICATIONS

The present application is a continuation application of an International Application No. PCT/CN2024/114995, filed on Aug. 28, 2024, which claims priority to Chinese Application No. 202411173816.4, filed on Aug. 23, 2024, the content of which is incorporated herein by reference in their entirety.

### TECHNICAL FIELD

The present application relates to the technical field of displays, and in particular to display panels and display devices.

### BACKGROUND

Micro-Light-emitting Diodes (Micro-LED, also known as Si-uLED) have been widely studied as an optimal solution in the field of AR display due to their small size and high brightness.

A vertically stacked full-color Micro-LED structure has a higher Pixels Per Inch (PPI) than the PPI of a horizontally stacked one, so that the display can display images at a higher PPI, thereby realizing a better fidelity. As shown in FIG. 1, a vertically stacked full-color pixel structure includes a red epitaxial layer 1, a green epitaxial layer 2, and a blue epitaxial layer 3 stacked vertically in sequence, and a metal bonding layer 4 is disposed between two adjacent epitaxial layers. Due to an opaque characteristic of metal, an upper component blocks light-emitting of a lower component, so that the light-emitting efficiency is significantly reduced.

### SUMMARY

Embodiments of the present application provide a display panel and a display device to solve at least the problem that the pixel light-emitting efficiency in an existing display panel is significantly reduced due to the opacity of a metal bonding layer.

In a first aspect, embodiments of the present application provide a display panel, including: a driving substrate; at least two light-emitting units, stacked on the driving substrate in sequence along a light-emitting direction of the display panel; and a reflecting layer, disposed between two adjacent light-emitting units; where, the reflecting layer includes a first reflecting unit and a second reflecting unit disposed at an interval, the first reflecting unit is disposed between two adjacent light-emitting units, the second reflecting unit is disposed at a periphery of the first reflecting unit, and the first reflecting unit and the second reflecting unit cooperate to make part of light of the light-emitting units emit in a direction perpendicular to the driving substrate after a secondary reflection.

In a second aspect, embodiments of the present application further provide a display device, including a display panel, which includes a driving substrate; at least two light-emitting units, stacked on the driving substrate in sequence along a light a light-emitting direction of the display panel; and a reflecting layer, disposed between two adjacent light-emitting units; where, the reflecting layer includes a first reflecting unit and a second reflecting unit disposed at an interval, the first reflecting unit is disposed between two adjacent light-emitting units, the second reflecting unit is disposed at a periphery of the first reflecting unit, and the first reflecting unit and the second reflecting unit cooperate to make part of light of the light-emitting units emits in a direction perpendicular to the driving substrate after a secondary reflection.

### BRIEF DESCRIPTION OF THE DRAWINGS

FIG. 1 is a diagram of a first stacking of a display panel provided in an embodiment of the present application;

FIG. 2 is a diagram of a second stacking of a display panel provided in an embodiment of the present application;

FIG. 3 is a diagram of a third stacking of a display panel provided in an embodiment of the present application;

FIG. 4 is a top view of a first lower end face of a first reflecting unit and a third reflecting unit provided in an embodiment of the present application;

FIG. 5 is a top view of a second lower end face of a first reflecting unit and a third reflecting unit provided in an embodiment of the present application;

FIG. 6 is a diagram of a fourth stacking of a display panel provided in an embodiment of the present application;

FIG. 7 is a schematic diagram of a material of a reflecting layer provided in an embodiment of the present application;

FIG. 8 is a simulation diagram of a first reflectivity of a reflecting layer provided in an embodiment of the present application;

FIG. 9 is a simulation diagram of a second reflectivity of a reflecting layer provided in an embodiment of the present application;

FIG. 10 is a simulation diagram of a third reflectivity of a reflecting layer provided in an embodiment of the present application;

FIG. 11 is a schematic diagram of a process realization of a reflecting layer provided in an embodiment of the present application; and

FIG. 12 is a schematic diagram of a structure of a display device provided in an embodiment of the present application.

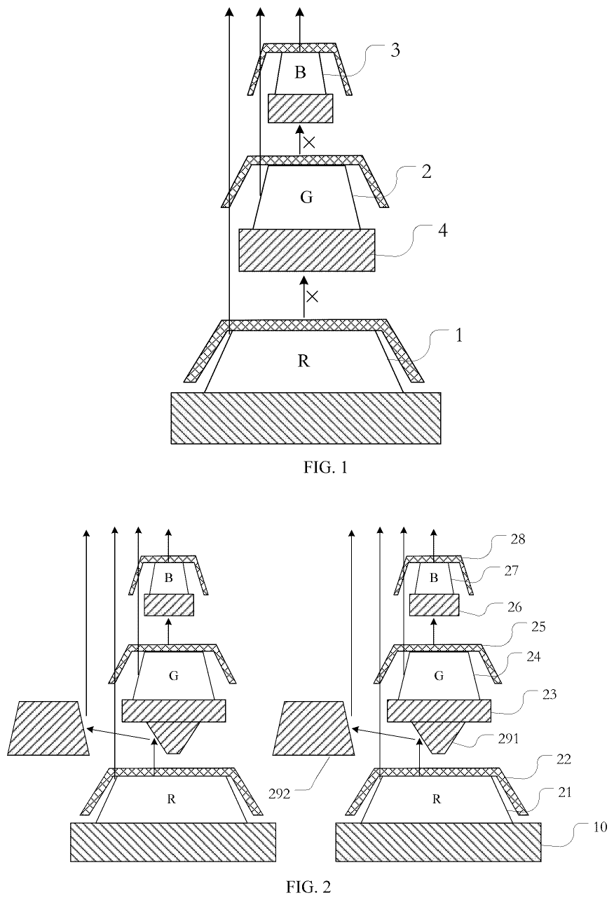

### DETAILED DESCRIPTION

In the following, the solutions in the embodiments of the present application are clearly and completely described with reference to the accompanying drawings. The solutions described is only used to clarify and explain the nature of the present application, and should not be regarded as a limitation on the scope of protection of the present application.

In addition, “multiple” in the embodiments of the present application refers to two or more. The “first” and “second” in the embodiments of the present application are used to distinguish different features, without indicating any order, quantity or importance.

The direction terms mentioned in the present application, such as “on”, “under”, “front”, “rear”, “left”, “right”, “inside”, “outside”, “side”, etc., are only the directions in the accompanying drawings. The direction terms used in this paper are used to clarify and explain the present application, not to limit the scope of protection of the present application.

In the accompanying drawings, components with the same structure are represented by the same numeral, and components with similar structure or function are represented by similar numerals. In addition, in order to facilitate understanding and description, size and thickness of each component shown in the accompanying drawings are arbitrary, and the present application does not limit the size and thickness of each component.

Each embodiment provided in the present application is similar, and features of different embodiments may be combined with each other.

The description order of the following embodiments is not used as a limitation on the preferred order of embodiments.

As shown in FIG. 2, an embodiment of the present application provides a display panel, including a driving substrate 10, at least two light-emitting units, and a reflecting layer disposed between two adjacent light-emitting units.

Furthermore, the reflecting layer includes a first reflecting unit 291 and a second reflecting unit 292. The first reflecting unit 291 is disposed between two adjacent light-emitting units, and the second reflecting unit 292 is disposed at a periphery of the first reflecting unit 291. The first reflecting unit 291 and the second reflecting unit 292 cooperate to make part of light of the light-emitting units emit in a direction perpendicular to the driving substrate 10 after a secondary reflection.

Beneficial effects provided in the embodiments of the present application include at least the follows.

The embodiments of the present application provide a display panel and a display device. The display panel includes a driving substrate, a light-emitting unit, and a reflecting layer. At least two light-emitting units are stacked on the driving substrate in sequence along the light-emitting direction of the display panel. The reflecting layer is disposed between two adjacent light-emitting units. The reflecting layer includes a first reflecting unit and a second reflecting unit disposed at an interval. The first reflecting unit is disposed between two adjacent light-emitting units, and the second reflecting unit is disposed at a periphery of the first reflecting unit. The first reflecting unit and the second reflecting unit cooperate to make part of light of the light-emitting unit emit in a direction perpendicular to the driving substrate after a secondary reflection. An emitting light of an epitaxial layer is reflected by the reflecting layer, so that a reflected light can be emitted in a direction perpendicular to the driving substrate. At least, it solves the problem that the pixel light-emitting efficiency is significantly reduced due to the opacity of the metal bonding layer in the existing display panel, and the output efficiency is effectively improved.

In an embodiment, the present application takes a stacking arrangement of three light-emitting units as an example to illustrate. Referring to FIG. 2, the light-emitting unit includes a first light-emitting unit, a second light-emitting unit, and a third light-emitting unit stacked on a driving substrate 10 in sequence along a light-emitting direction of the display panel. The display panel further includes a first metal bonding layer 23, disposed between the first light-emitting unit and the second light-emitting unit; and a second metal bonding layer 26, disposed between the second light-emitting unit and the third light-emitting unit. The first light-emitting unit includes a first epitaxial layer 21 and a first charge generation layer 22 stacked in sequence along a light-emitting direction of the display panel. The second light-emitting unit includes a second epitaxial layer 24 and a second charge generation layer 25 stacked in sequence along the light-emitting direction of the display panel. The third light-emitting unit includes a third epitaxial layer 27 and a third charge generation layer 28 stacked in sequence along the light-emitting direction of the display panel.

It should be noted that the reflecting layer may be disposed between the first metal bonding layer 23 and the first charge generation layer 22, or between the second metal bonding layer 26 and the second charge generation layer 25; or two reflecting layers may be respectively disposed between the first metal bonding layer 23 and the first charge generation layer 22, and between the second metal bonding layer 26 and the second charge generation layer 25. The above is illustrated by taking three stacked light-emitting units as an example. In case that the number of the light-emitting units is two, only one reflecting layer may be disposed. In case that the light-emitting units include four light-emitting units disposed in a stacked mode, three layers of reflecting layer may be disposed, that is, the reflecting layer can be flexibly arranged according to the actual product application. However, the present application embodiment is not limited to that.

An orthographic projection, on the driving substrate 10, of the first reflecting unit 291 is partially overlapped with an orthographic projection, on the driving substrate 10, of the first metal bonding layer 23, and an orthographic projection area, on the driving substrate 10, of the first reflecting unit 291 is smaller than an orthographic projection area, on the driving substrate 10, of the first metal bonding layer 23. A width of the first reflecting unit 291 in a vertical direction gradually increases along a vertical light-emitting path of the first epitaxial layer 21.

The epitaxial layer mentioned in the embodiments of the present application refers to a semiconductor thin film layer formed by epitaxial growth technology on the substrate, which is epitaxially grown mainly by metal organic chemical vapor deposition (MOCVD) technology. MOCVD is a commonly used semiconductor material growth technology, in which metal organic compounds and hydrogen gas are transported to the substrate surface at high temperature, and then chemical reactions occur to generate a required semiconductor film. The epitaxial layer of Micro-LED is mainly composed of gallium nitride (GaN) and other related compounds. GaN is a wide band-gap semiconductor material, which is commonly used in the manufacture of blue and green LEDs. By adjusting a ratio of indium (In) and aluminum (Al) in GaN, light-emitting diodes with different wavelengths can be fabricated. The first epitaxial layer 21, the second epitaxial layer 24 and the third epitaxial layer 27 in the embodiments of the present application respectively correspond to one of a red epitaxial layer, a green epitaxial layer or a blue epitaxial layer.

In the display panel provided in this embodiment of the present application, the reflecting layer can be disposed between the first charge generation layer 22 and the first metal bonding layer 23, or between the second charge generation layer 25 and the second metal bonding layer 26.

In the display panel described above, the first epitaxial layer, the first charge generation layer, the first metal bonding layer, the second epitaxial layer, the second charge generation layer, the second metal bonding layer, the third epitaxial layer, and the third charge generation layer are stacked in sequence in the vertical direction of the driving substrate. The display panel further includes a reflecting layer, disposed between the first charge generation layer and the first metal bonding layer, or between the second charge generation layer and the second metal bonding layer. The emitting light of the epitaxial layer is reflected by the reflecting layer, so that the reflected light can be emitted in the direction perpendicular to the driving substrate. At least, it solves the problem that the pixel light-emitting efficiency is significantly reduced due to the opacity of the metal bonding layer in the existing display panel, and the output efficiency is effectively improved.

In an embodiment, the first epitaxial layer 21, the second epitaxial layer 24, and the third epitaxial layer 27 respectively correspond to tricolor epitaxial layers of a red epitaxial layer, a green epitaxial layer, and a blue epitaxial layer, or correspond to a blue primary color epitaxial layer coated with red fluorescent material, a blue primary color epitaxial layer coated with green fluorescent material and a blue primary color epitaxial layer. Certainly, the first epitaxial layer 21 may also be a green epitaxial layer or a blue epitaxial layer, in which the corresponding color of different epitaxial layers maybe adjusted according to the actual needs, which is not limit in the embodiments of the present application. In the embodiments and the accompanying drawings of the present application, the first epitaxial layer 21, the second epitaxial layer 24 and the third epitaxial layer 27 correspond to the tricolor epitaxial layers of the red epitaxial layer, the green epitaxial layer and the blue epitaxial layer respectively as examples for display and explanation.

Continuing to refer to FIG. 2, in an embodiment, an orthographic projection area, on the driving substrate 10, of the first epitaxial layer 21 is larger than an orthographic projection area, on the driving substrate 10, of the second epitaxial layer 24, and an orthographic projection area, on the driving substrate 10, of the second epitaxial layer 24 is larger than an orthographic projection area, on the driving substrate 10, of the third epitaxial layer 27. As such, a bottom epitaxial layer can emit light from a periphery of an upper epitaxial layer.

In an embodiment, the orthographic projection area of the metal bonding layer is reduced from bottom to top, which can also improve the light-emitting efficiency of the bottom epitaxial layer.

In an embodiment, the first reflecting layer 29 and the first metal bonding layer 23 are formed by the same metal material. The first reflecting layer 29 and the first metal bonding layer 23 can be evaporated or deposited using the same metal material, so that a sum of a thickness of the first metal bonding layer 23 and a thickness of the first reflecting unit 291 is equal to or infinitely approximate to a thickness of the second reflecting unit 292. That is, the first metal bonding layer 23 is made into a special-shaped structure to form the first reflecting layer 29, and the first metal bonding layer 23 and the first reflecting layer 29 can be uniformly set as the first metal bonding layer.

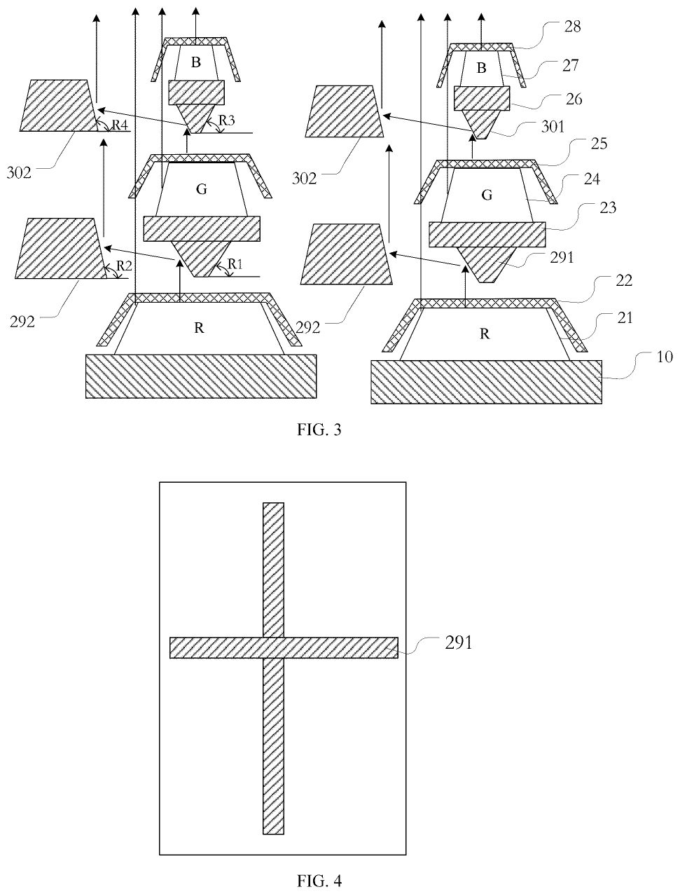

Referring to FIG. 3, in an embodiment, in order to further improve the light-emitting efficiency, the reflecting layer can be set to two layers, that is, a first reflecting layer 29 is disposed between the first charge generation layer 22 and the first metal bonding layer 23, and a second reflecting layer 30 is disposed between the second charge generation layer 25 and the second metal bonding layer 26. The second reflecting layer 30 includes a third reflecting unit 301 and a fourth reflecting unit 302.

The orthographic projection, on the driving substrate 10, of the third reflecting unit 301 partially overlaps with orthographic projections, on the driving substrate 10, of the second charge generation layer 25 and the second metal bonding layer 26, and the orthographic projection area, on the driving substrate 10, of the third reflecting unit 30 is smaller than the orthographic projection area, on the driving substrate 10, of the second metal bonding layer 26. A width, in the vertical direction, of the third reflecting unit 301 gradually increases along a vertical light-emitting path of the second epitaxial layer 24. A fourth reflecting unit 302 is disposed on a periphery of the third reflecting unit 301 and forms a reflection fit with the third reflecting unit 301 to make the reflected light emit along the vertical direction of the driving substrate 10. Transparent material is filled between the fourth reflecting unit 302 and the third reflecting unit 301.

In an embodiment, the first reflecting layer 29 and the first metal bonding layer 23 are formed by the same metal material; and the second reflecting layer 29 and the second metal bonding layer 26 are formed by the same metal material. Referring to FIG. 3, the first reflecting layer 29 and the first metal bonding layer 23 can be evaporated or deposited using the same material, so that a sum of a thickness of the first metal bonding layer 23 and a thickness of the first reflecting unit 291 is equal to or infinitely approximate to a thickness of the second reflecting unit 292. The second reflecting layer 29 and the second metal bonding layer 26 can also be evaporated or deposited using the same material, so that a sum of a thickness of the second metal bonding layer 26 and a thickness of the third reflecting unit 301 is equal to or infinitely approximate to a thickness of the fourth reflecting unit 302. That is, the first metal bonding layer 23 is set into a special-shaped structure to form the first reflecting layer, and making the second metal bonding layer 26 into a special-shaped structure to form the second reflecting layer, that is, the first metal bonding layer and the first reflecting layer shown in FIG. 3 can be unified as the first metal bonding layer, and the second metal bonding layer and the second reflecting layer shown in FIG. 3 can be unified as the second metal bonding layer.

As shown in FIG. 4 and FIG. 5, in an embodiment, the first reflecting unit 291 and the third reflecting unit 301 are in a shape of “+” or “−” on a horizontal section of the display panel. It can also be understood that a top view of a lower end face of the first reflecting unit 291 and the third reflecting unit 301 in FIG. 3 is in a shape of “+” or “−”.

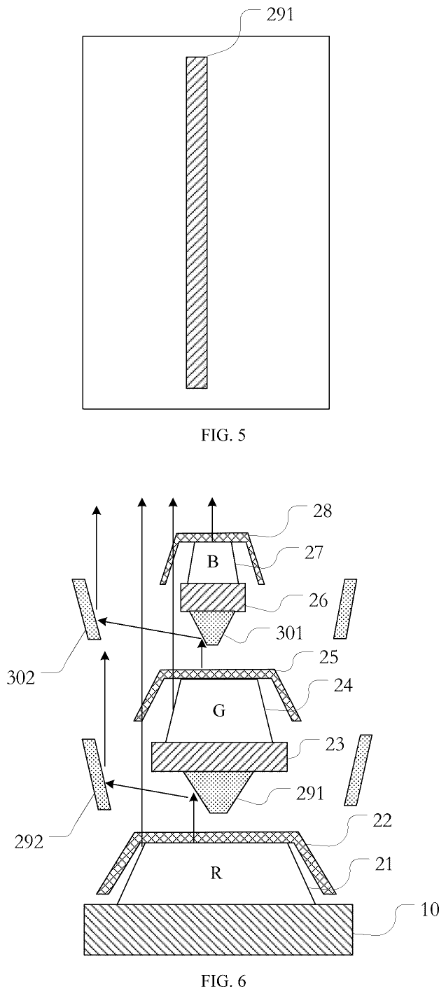

As shown in FIG. 6, in an optional embodiment, the first reflecting layer 29 and the second reflecting layer 30 can also be specific reflecting layers formed by other reflective materials rather than the material of the metal bonding layer. A first bulge is disposed on a side, facing to the first charge generation layer 22, of a first metal bonding layer 23. The first reflecting layer 29 includes multiple inorganic films stacked on a sidewall of the first bulge. A second bulge is disposed on a side, facing the second charge generation layer 25, of the second metal bonding layer 26. The second reflecting layer 30 includes multiple inorganic films stacked on a sidewall of the second bulge. That is, the first reflecting layer 29 and the second reflecting layer 30 can be stacked by several film layers formed by inorganic materials, for example, can be stacked by several film layers made of TiO or SiO.

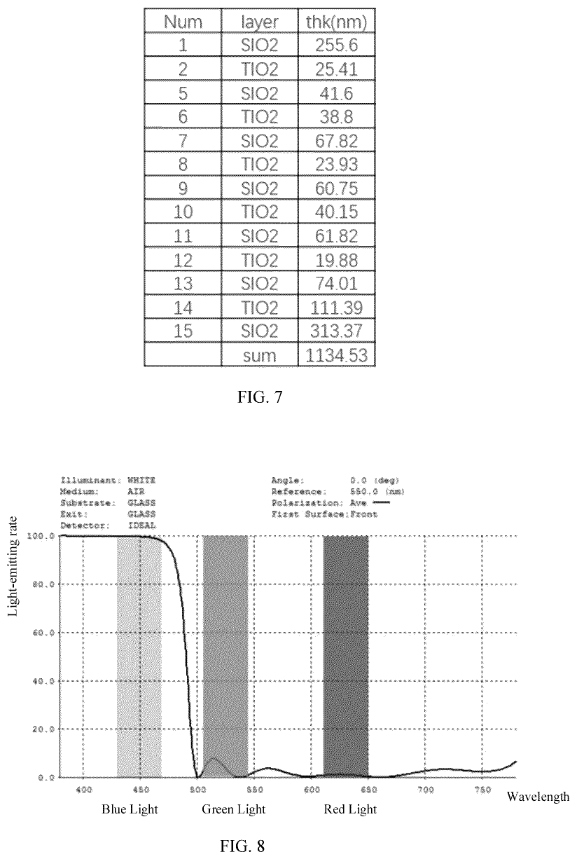

Referring to FIG. 7, an example is given in this embodiment of the present application. The first reflecting layer 29 and the second reflecting layer 30 are formed by stacking 15 film layers made of TiO or SiO. A material and a corresponding thickness of each layer are shown in FIG. 7. Through adopting the reflecting layer shown in FIG. 7, a better reflection effect can be realized. The simulation results of the reflection efficiency of the tricolor light of the red light, the green light, and the blue light are shown in FIG. 8. It can be seen that the transmittance of the reflective material for blue light is close to 100%, and the transmittance of green light and red light is close to 0. Therefore, the reflectivity of green light and red light is extremely high. In the mainstream laminated structure, the blue light-emitting layer is generally arranged on the top layer, so that the light emitting is unblocked. The red light-emitting layer and the green light-emitting layer are arranged below, so that the metal bonding layer would blocks light emitting. Therefore, the use of this reflective material can effectively improve the light-emitting efficiency of red light and green light.

In an embodiment, a value range of an angle R1 between a reflective surface of the first reflecting unit 291 and the driving substrate 10 is 0°<R1<90°; and a value range of an angle R2 between a reflective surface of the second reflecting unit 292 and the driving substrate 10 is 90°<R2<180°.

In an embodiment, a value range of an angle R3 between a reflective surface of the third reflecting unit 301 and the driving substrate 10 is 0°<R3<90°; and the value range of the angle R4 between the reflective surface of the fourth reflecting unit 302 and the driving substrate 10 is 90°<R4<180°.

In a solution, the reflective surface of the first reflecting unit is parallel to the reflective surface of the second reflecting unit, and the reflective surface of the third reflecting unit is parallel to the reflective surface of the fourth reflecting unit, so that the reflected light can be emitted in a direction perpendicular to the driving substrate.

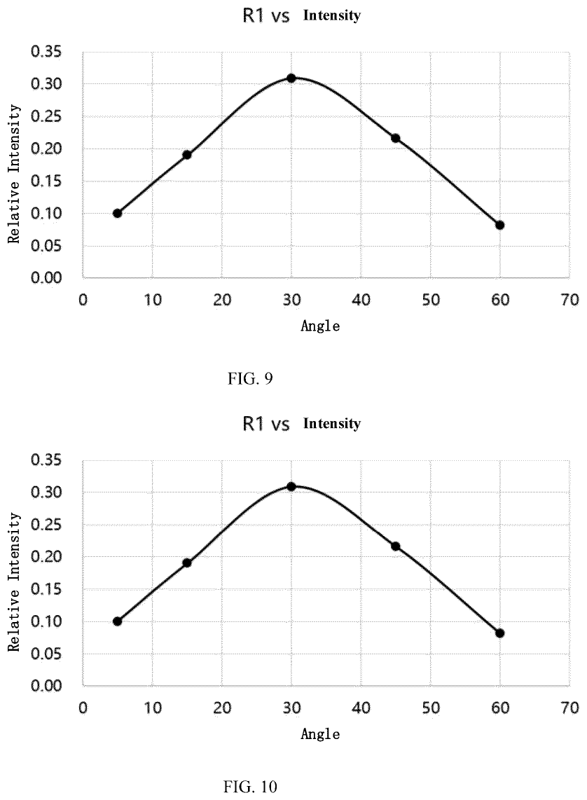

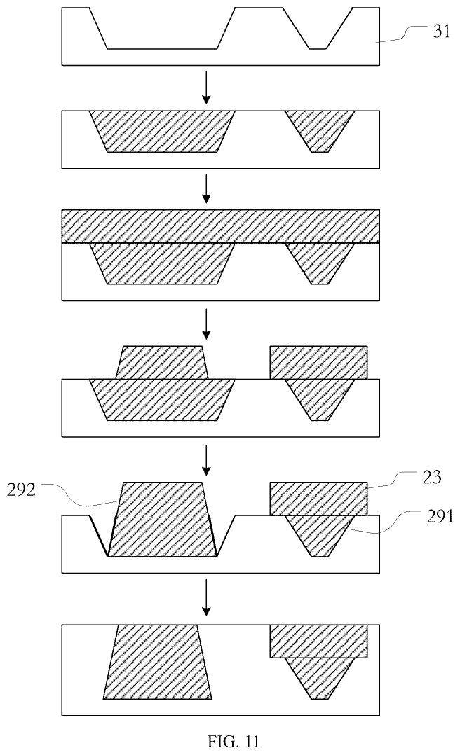

As shown in FIG. 9 and FIG. 10, a relationship between an angle value of R1 and a reflection intensity is parabolic, and a relationship between an angle value of R2 and an emission intensity is also parabolic. The specific correspondence is shown in Table 1. When the angle value of R1 is from 20° to 40°, the reflection intensity is higher, and the optimal effect is realized when R1=30°. Correspondingly, when the angle value of R2 is 110° to 130°, the reflection intensity is higher, and the optimal effect is realized when R2=120°. When the reflective surface of the first reflecting unit is parallel to the reflective surface of the second reflecting unit, the reflection effect is the best.

TABLE 1

| R1 | R2 | Intensity |
|---|---|---|
| 5 | 95 | 0.06 |
| 10 | 100 | 0.13 |
| 20 | 110 | 0.23 |
| 30 | 120 | 0.31 |
| 42.5 | 132.5 | 0.29 |
| 30 | 5 | 0.10 |
| 30 | 15 | 0.19 |
| 30 | 30 | 0.31 |
| 30 | 45 | 0.22 |
| 30 | 60 | 0.08 |
| 30 | 75 | 0.06 |

The embodiments of the present application also provides a manufacturing method for the display panel, including: stacking the first epitaxial layer, the first charge generation layer, the first reflecting layer, the first metal bonding layer, the second epitaxial layer, the second charge generation layer, the second metal bonding layer, the third epitaxial layer, and the third charge generation layer on the driving substrate in sequence, wherein the first reflecting layer includes the first reflecting unit and the second reflecting unit.

With reference to FIG. 11, taking the material of the first reflecting layer consistent with the material of first metal bonding layer as an example, a stacking method of the first reflecting layer includes:
depositing of a first passivation layer on the first charge generation layer;
patterning the first passivation layer to form a target morphology corresponding to the first reflecting unit and the second reflecting unit;
filling in a corresponding material of the reflecting layer to fill the target morphology;
filling in a corresponding material of the first metal bonding layer to form the first metal bonding layer;
forming a morphology of the first reflecting layer and the first metal bonding layer by ion beam etching; and
filling in a second passivation layer to fill the morphology of the reflecting layer and the first metal bonding layer.

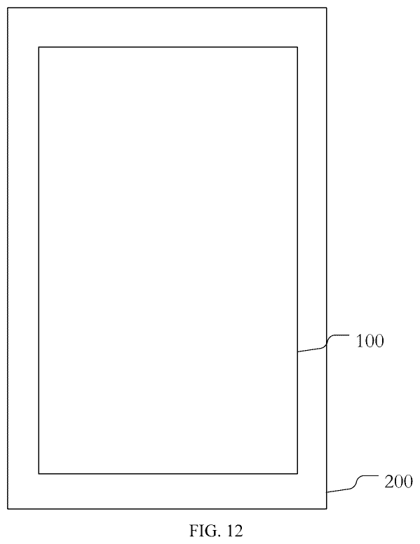

As shown in FIG. 12, an embodiment of the present application provides a display device 200, including the display panel 100 described in any one of the above embodiments.

The display device may be: a mobile phone, a tablet, a television, a monitor, a laptop, a digital photo frame, a navigator, and any other products or components with display functions.

In this paper, specific embodiments are used to explain the principle and implementation of the present application. The above embodiments are only used to help understand the solutions and nature of the present application. At the same time, for the technical personnel in this field, according to the nature of the present application, changes can be made in the specific solutions and application scope. In summary, the content of the specification should not be understood as a limitation on the present application.

What is claimed is:

1. A display panel, comprising:
a driving substrate;
at least two light-emitting units, stacked on the driving substrate in sequence along a light-emitting direction of the display panel; and
a reflecting layer, disposed between two adjacent light-emitting units; wherein, the reflecting layer comprises a first reflecting unit and a second reflecting unit disposed at an interval, the first reflecting unit is disposed between two adjacent light-emitting units, the second reflecting unit is disposed at a periphery of the first reflecting unit, and the first reflecting unit and the second reflecting unit cooperate to make part of light of the light-emitting units emit in a direction perpendicular to the driving substrate after a secondary reflection.

2. The display panel of claim 1, wherein
the light-emitting unit comprises a first light-emitting unit, a second light-emitting unit, and a third light-emitting unit stacked on the driving substrate in sequence along a light-emitting direction of the display panel;
the display panel further comprises a first metal bonding layer, disposed between the first light-emitting unit and the second light-emitting unit; and a second metal bonding layer, disposed between the second light-emitting unit and the third light-emitting unit; wherein
the first light-emitting unit comprises a first epitaxial layer and a first charge generation layer stacked in sequence along a light-emitting direction of the display panel;
the second light-emitting unit comprises a second epitaxial layer and a second charge generation layer stacked in sequence along the light-emitting direction of the display panel; and/or
the third light-emitting unit comprises a third epitaxial layer and a third charge generation layer stacked in sequence along the light-emitting direction of the display panel; and wherein
the reflecting layer is disposed between the first metal bonding layer and the first charge generation layer, or
the reflecting layer is disposed between the second metal bonding layer and the second charge generation layer.

3. The display panel of claim 2, wherein an orthographic projection, on the driving substrate, of the first reflecting unit is partially overlapped with an orthographic projection, on the driving substrate, of the first metal bonding layer; an orthographic projection area, on the driving substrate, of the first reflecting unit is smaller than an orthographic projection area, on the driving substrate, of the first metal bonding layer; and a width of the first reflecting unit in a vertical direction gradually increases along a vertical light-emitting path of the first epitaxial layer.

4. The display panel of claim 2, wherein an orthographic projection area, on the driving substrate, of the first epitaxial layer is larger than an orthographic projection area, on the driving substrate, of the second epitaxial layer, and an orthographic projection area, on the driving substrate, of the second epitaxial layer is larger than an orthographic projection area, on the driving substrate, of the third epitaxial layer.

5. The display panel of claim 2, wherein the reflecting layer and, the first metal bonding layer and/or the second metal bonding layer are formed by a same metal material.

6. The display panel of claim 2, wherein a first bulge is disposed on a side, facing to the first charge generation layer, of a first metal bonding layer, and the first reflecting layer comprises multiple inorganic films stacked on a sidewall of the first bulge.

7. The display panel of claim 2, wherein the first reflecting unit is in a shape of “+” or “−” on a horizontal section of the display panel.

8. The display panel of claim 2, wherein
a value range of an angle R1 between a reflective surface of the first reflecting unit and the driving substrate 10 is 0°<R1<90°; and
a value range of an angle R2 between a reflective surface of the second reflecting unit and the driving substrate 10 is 90°<R2<180°.

9. The display panel of claim 8, wherein the reflective surface of the first reflecting unit is parallel to the reflective surface of the second reflecting unit.

10. The display panel of claim 2, wherein the first epitaxial layer, the second epitaxial layer, and the third epitaxial layer respectively correspond to tricolor epitaxial layers of a red epitaxial layer, a green epitaxial layer and a blue epitaxial layer, or correspond to a blue primary color epitaxial layer coated with red fluorescent material, a blue primary color epitaxial layer coated with green fluorescent material and a blue primary color epitaxial layer.

11. A display device, comprising a display panel, wherein the display panel comprises
a driving substrate;
at least two light-emitting units, stacked on the driving substrate in sequence along a light a light-emitting direction of the display panel; and
a reflecting layer, disposed between two adjacent light-emitting units; wherein, the reflecting layer comprises a first reflecting unit and a second reflecting unit disposed at an interval, the first reflecting unit is disposed between two adjacent light-emitting units, the second reflecting unit is disposed at a periphery of the first reflecting unit, and the first reflecting unit and the second reflecting unit cooperate to make part of light of the light-emitting units emits in a direction perpendicular to the driving substrate after a secondary reflection.

12. The display device of claim 11, wherein
the light-emitting unit comprises a first light-emitting unit, a second light-emitting unit, and a third light-emitting unit stacked on a driving substrate in sequence along a light-emitting direction of the display panel;
the display panel further comprises a first metal bonding layer, disposed between the first light-emitting unit and the second light-emitting unit; and a second metal bonding layer, disposed between the second light-emitting unit and the third light-emitting unit; wherein
the first light-emitting unit comprises a first epitaxial layer and a first charge generation layer stacked in sequence along a light-emitting direction of the display panel;
the second light-emitting unit comprises a second epitaxial layer and a second charge generation layer stacked in sequence along the light-emitting direction of the display panel; and/or
the third light-emitting unit comprises a third epitaxial layer and a third charge generation layer stacked in sequence along the light-emitting direction of the display panel; and wherein
the reflecting layer is disposed between the first metal bonding layer and the first charge generation layer, or
the reflecting layer is disposed between the second metal bonding layer and the second charge generation layer.

13. The display device of claim 12, wherein an orthographic projection, on the driving substrate, of the first reflecting unit is partially overlapped with an orthographic projection, on the driving substrate, of the first metal bonding layer; an orthographic projection area, on the driving substrate, of the first reflecting unit is smaller than an orthographic projection area, on the driving substrate, of the first metal bonding layer; and a width of the first reflecting unit in a vertical direction gradually increases along a vertical light-emitting path of the first epitaxial layer.

14. The display device of claim 12, wherein an orthographic projection area, on the driving substrate, of the first epitaxial layer is larger than an orthographic projection area, on the driving substrate, of the second epitaxial layer, and an orthographic projection area, on the driving substrate, of the second epitaxial layer is larger than an orthographic projection area, on the driving substrate, of the third epitaxial layer.

15. The display device of claim 12, wherein the reflecting layer and, the first metal bonding layer and/or the second metal bonding layer are formed by a same metal material.

16. The display device of claim 12, wherein a first bulge is disposed on a side, facing to the first charge generation layer, of a first metal bonding layer, and the first reflecting layer comprises multiple inorganic films stacked on a sidewall of the first bulge.

17. The display device of claim 12, wherein the first reflecting unit is in a shape of “+” or “−” on a horizontal section of the display panel.

18. The display device of claim 12, wherein
a value range of an angle R1 between a reflective surface of the first reflecting unit and the driving substrate 10 is 0°<R1<90°; and
a value range of an angle R2 between a reflective surface of the second reflecting unit and the driving substrate 10 is 90°<R2<180°.

19. The display device of claim 18, wherein the reflective surface of the first reflecting unit is parallel to the reflective surface of the second reflecting unit.

20. The display device of claim 12, wherein the first epitaxial layer, the second epitaxial layer and the third epitaxial layer respectively correspond to tricolor epitaxial layers of a red epitaxial layer, a green epitaxial layer and a blue epitaxial layer, or correspond to a blue primary color epitaxial layer coated with red fluorescent material, a blue primary color epitaxial layer coated with green fluorescent material and a blue primary color epitaxial layer.
